(19) United States
(12) Patent Application Publication
(10) Pub. No.: US 2021/0151616 A1
(43) Pub. Date: May 20, 2021

(54) INTEGRATED OPTICAL SENSOR OF THE SINGLE-PHOTON AVALANCHE PHOTODIODE TYPE, AND MANUFACTURING METHOD

(71) Applicant: STMicroelectronics (Crolles 2) SAS, Crolles (FR)

(72) Inventor: Didier DUTARTRE, Meylan (FR)

(73) Assignee: STMicroelectronics (Crolles 2) SAS, Crolles (FR)

(21) Appl. No.: 17/097,661

(22) Filed: Nov. 13, 2020

(30) Foreign Application Priority Data
Nov. 15, 2019 (FR) 1912771

(51) Int. Cl. H01L 31/0312; H01L 31/107

(52) U.S. Cl. CPC H01L 31/03125; H01L 27/14643; H01L 31/107

(57) ABSTRACT

An integrated optical sensor includes a photon-detection module of a single-photon avalanche photodiode type. The detection module includes a semiconductive active zone in a substrate. The semiconductive active zone includes a region that contains germanium with a percentage between 3% and 10%. This percentage range is advantageous because it makes it possible to obtain a material firstly containing germanium (which in particular increases the efficiency of the sensor in the infrared or near infrared domain) and secondly having no or very few dislocations(which facilitates the implementation of a functional sensor in integrated form).

### PRIORITY CLAIM

This application claims the priority benefit of French Application for Patent No. 1912771, filed on Nov. 15, 2019, the content of which is hereby incorporated by reference in its entirety to the maximum extent allowable by law.

### TECHNICAL FIELD

Embodiments and implementations relate to integrated optical sensors and, in particular, sensors comprising a single-photon detector, especially of a single-photon avalanche photodiode (SPAD) type.

### BACKGROUND

During the past years, an increasing number of applications such as facial recognition, virtual reality and automobile active safety have more and more often required compact low-cost high-performance imaging systems.

In this regard, imaging systems based on the time of flight measuring principle (commonly referred to by persons skilled in the art under the acronym “ToF”) and having a highly integrated structure and a precise and rapid performance, meet these requirements particularly well.

Such a so-called ToF imaging system generally emits optical-light radiation, for example of the infrared or laser type, towards an object located in its measurement field of view so as to measure the time of flight of this radiation, in other words the time that elapses between the emission thereof and the reception thereof by the imaging system after reflection on the object. Such a direct measurement is known to persons skilled in the art by the acronym “dToF” (“direct Time of Flight”).

To do this, several types of single-photon detectors can be used, such as detectors of the single-photon avalanche photodiode type commonly designated by a person skilled in the art by the acronym “SPAD” (“Single Photon Avalanche Diode”).

This type of detector is particularly used for applications using radiations the wavelength of which is located in the near infrared (for example between 0.8 micrometers and 1 micrometer).

And such applications, implemented in particular not only in time of flight sensors but also in CMOS imagers, are more and more numerous.

Generally, the sensors used are integrated silicon-based sensors.

However, silicon has low absorption capacity in the infrared and even in the near infrared (0.94 micrometers, for example). For example, a silicon substrate 1 micrometer thick has an absorption of 1.7% at 0.94 micrometers wavelength.

Furthermore, silicon devices have low sensitivity in the near infrared. For example, a silicon substrate 2 micrometers thick has a quantum efficiency of around 3% at 0.94 micrometers wavelength.

Thus, there is a need to improve the performance of an optical sensor using in particular one or more single-photon detectors such as detectors of the single-photon avalanche photodiode (SPAD) type, particularly in the near infrared domain, especially in terms of absorption and sensitivity.

### SUMMARY

The inventor observed that it is possible to meet the foregoing need by replacing silicon with a material having in particular better infrared absorption while satisfying strict constraints such as for example:

integrability with microelectronic components located on the front face of a substrate (“Front-End”) as well as with monocrystalline silicon;

compatibility with the various methods for manufacturing other semiconductor devices (diodes, transistors, resistors, etc.);

integrability in the active part of semiconductor devices (avalanche diode);

a sufficiently low generation of minority carriers in darkness; and

a defectiveness which is as low as possible.

Such a material is then advantageously resistant to temperature, capable of being subjected to repeated avalanches of carriers, having a perfect quality of interface with silicon and good quality of interface with dielectric materials such as silicon dioxide and in general having a good structural and electronic quality (no or very few structural defects, no or very few contaminants) and therefore long lives of minority carriers.

It is thus proposed to incorporate germanium or a silicon-germanium alloy in the active part of the detector.

Thus, according to one aspect, an integrated optical sensor comprises at least one photon-detection module of the single-photon avalanche photodiode type, said detection module comprising, in a substrate, a semiconductive active zone containing germanium.

The presence of germanium in the semiconductive active zone increases the performance of the optical sensor, in particular in the near infrared domain, especially in terms of absorption and sensitivity.

According to one embodiment, the active zone comprises a region containing silicon and germanium, the atomic percentage of the germanium in said region being comprised between 3 and 10.

This range of atomic percentage of germanium (between 3% and 10%) is particularly advantageous, since it makes it possible to obtain a material firstly containing germanium (which in particular increases the efficiency of the sensor in the infrared or near infrared domain) and secondly having no or very few dislocations, which facilitates the implementation of a functional sensor in integrated form.

More precisely, with such a percentage, the absorption of a radiation in the near infrared (0.94 μm for example) is increased in a ratio of 30% to 100% compared with a silicon active region (not containing any germanium).

Likewise, the quantum efficiency is increased in a ratio of 30% to 100% compared with the quantum efficiency of the same active region comprising only silicon.

A region containing silicon and germanium with such an atomic percentage can be obtained with a silicon-germanium alloy or, in a variant, with an alternation of layers of silicon and layers of silicon-germanium.

When an alternation of layers of silicon-germanium and silicon is used, the atomic percentages of germanium in each of the layers of silicon-germanium will be chosen so that the mean total atomic percentage of germanium also lies in the range 3-10%.

Provision can also be made for generating a gradual composition of germanium (Ge) at the silicon/germanium-silicon (SiGe—Si) interfaces, perpendicular to the substrate.

The composition gradient is advantageously chosen so as to remove any possibility of having a contrary electrical field for the carriers generated.

This composition gradient would then preferentially be chosen less than 2% per nm, for example 1% per nm.

It should be noted in this regard that, the various layers of the sensor advantageously being produced by epitaxy, the thermal budgets subsequent to the epitaxy are often sufficient to create this gradual layer by interdiffusion of the silicon and germanium atoms.

Moreover, contrary to the general case where thick epitaxies of SiGe are accompanied by a very high density of mesh disagreement dislocation at the SiGe/Si interface and a high density of emerging dislocations on the surface, and which are not compatible with the transistors necessary for the functioning of the pixel, the epitaxies performed here are free or almost free from these defects because in particular of the preferential range of atomic percentage of germanium (between 3% and 10%).

Consequently these epitaxies are compatible with storage/reading transistors and with the manufacture of high-quality pixels, that is to say with a small number of parasitic avalanches (in darkness).

Whereas it would be possible for the semiconducting active zone containing germanium to occupy the entire depth of the substrate, it may prove to be advantageous for said region containing germanium to be located deep and at a distance from a top face of the substrate.

This makes it possible, for example, for the active zone to comprise a layer of silicon located between said top face and said region.

Such a top layer of silicon present over the entire wafer facilitates the compatibility of the sensor with integration of the other components on the semiconductor wafer.

According to one embodiment, the sensor may comprise a plurality of detection modules arranged in lines or in a matrix, for example.

According to another aspect, an imaging system, for example a camera, comprises at least one sensor as defined above.

According to another aspect, an electronic apparatus, for example of the tablet or cellular mobile telephone type, comprises at least one imaging system as defined above.

According to yet another aspect, a method for producing an optical sensor comprises at least one photon-detection module of the single-photon avalanche photodiode type, the method comprising the production, in a substrate, of a semiconducting active zone of said at least one module, containing germanium.

According to one embodiment, the production of the active zone comprises a formation of a region containing silicon and germanium, the atomic percentage of the germanium in said region being comprised between 3 and 10.

The formation of said region may comprise at least one epitaxy, for example an epitaxy of a layer of a silicon-germanium alloy.

In a variant, the formation of the region may comprise formations, by successive epitaxies, of an alternation of layers of silicon and layers of silicon-germanium.

According to one embodiment, the production of the active zone comprises a formation of a layer of silicon covering said region.

The formation of this layer of silicon may also comprise an epitaxy.

According to one embodiment, the method comprises a formation of an electrode with N-type conductivity of the sensor by localized ion implantation performed before the formation by epitaxy of the region containing silicon and germanium.

The method may also comprise a formation of an electrode of the P-type conductivity by localized ion implantation.

Likewise the contact zone of the sensor, of the P+ type conductivity, can be performed by localized ion implantation.

### BRIEF DESCRIPTION OF THE DRAWINGS

Other advantages and features of the invention will emerge from an examination of the detailed description of embodiments and implementation, and the accompanying drawings, on which:

FIG. 1 is a cross-section of a photon detection module of the single-photon avalanche photodiode (SPAD) type;

FIG. 2 is a cross section of the SPAD implemented using an alternation of layers of silicon and layers of silicon-germanium;

FIG. 3 illustrates an embodiment of a method for manufacturing the active zone of the module in FIG. 1;

FIG. 4 illustrates an embodiment of a method for manufacturing the active zone of the module in FIG. 2;

FIG. 5 shows an integrated optical sensor comprising a plurality of detection modules arranged for example in rows or in a matrix;

FIG. 6 shows a sensor incorporated in an imaging system CM;

FIG. 7 shows an electronic apparatus that uses the sensor;

FIG. 8 is a cross-section of a photon detection module of the SPAD type which utilizes a concentration gradient.

### DETAILED DESCRIPTION

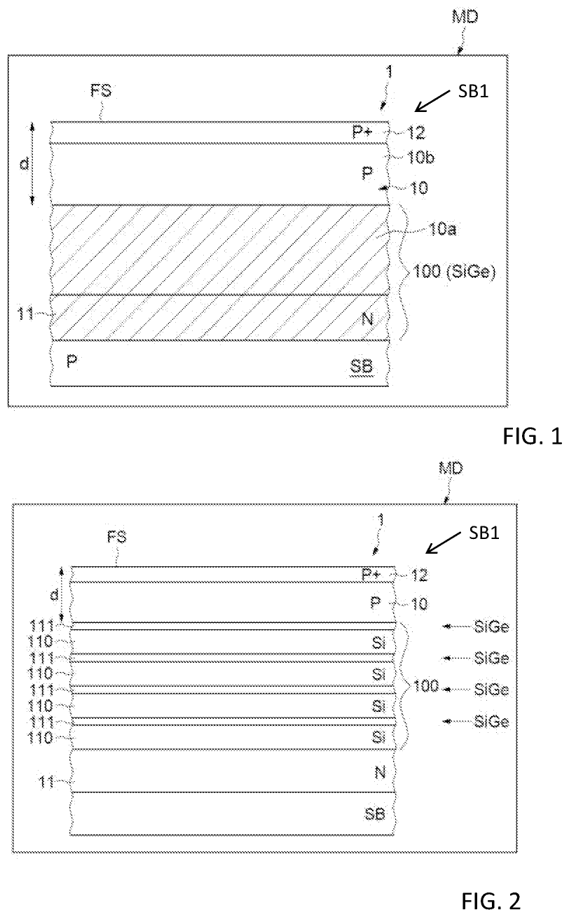

In FIG. 1, the reference MD designates overall a photon detection module of the single-photon avalanche photodiode (SPAD) type.

This detection module MD comprises, in a substrate SB1, a semiconductive active zone 1 containing germanium.

More precisely, in this embodiment, the active zone 1 comprises a region 100 containing silicon and germanium, the volume percentage of germanium in said region being comprised between 3 and 10%.

In FIG. 1, the various contacts and other elements of the SPAD detection module, which are conventional and known per se, have intentionally not been depicted, for reasons of simplification.

In the active zone 1, a deep N-doped layer 11, forming the N electrode of the photodiode, is located above a P-type support substrate SB.

The thickness of this layer 11 is, for example, around 1 micrometer and the concentration of dopants is, for example, around 2×10¹⁸ atoms of dopants (N-type) per cm³.

A very weakly P doped thick layer 10 is located above the N-doped layer 100.

This layer, referenced overall 10, comprises a bottom part 10a and a top part 10b.

The layer 10 forms the P electrode of the photodiode.

The region 100 of silicon-germanium incorporates the N-doped layer 11 as well as also incorporates the part 10a of the layer 10.

The thickness of the region 100, containing germanium, is around 1 micrometer, for example, and the atomic percentage of germanium is around 4.

The concentration of dopants (P type) in the part 10a of the layer 10 is, for example, zero (not intentionally doped) or around 10¹⁵ or 2×10¹⁵ at/cm³ or even less, while the concentration of dopants (P type) in the part 10b of the layer 10, located above the part 10a, is around 10¹⁸ to 4×10¹⁸ at/cm³.

The layer 10 is surmounted by a P+ doped top layer 12, with a concentration of dopants of around 10¹⁸ to 5×10¹⁸ at/cm³, for example.

In this example, the region 100 containing germanium is located deep and at a distance d from the top face FS of the substrate SB1.

On an indicative basis, this distance d may be around 0.5 μm for a region 100 having a thickness of around 1 μm.

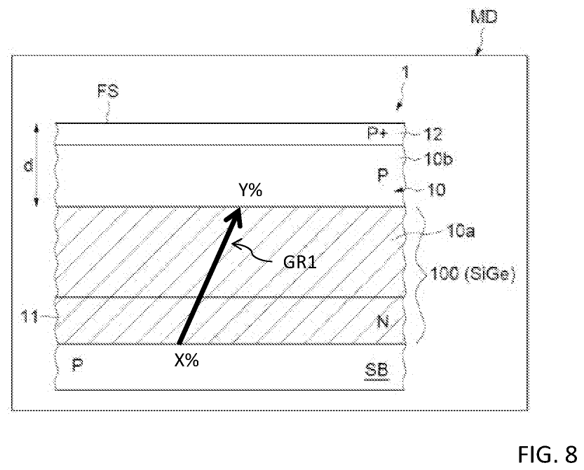

In a variant shown in FIG. 8, the region 100 may include silicon and germanium with a concentration gradient GR1 extending over a thickness of the region 100. The concentration gradient GR1 is a positive gradient in that the atomic percentage of germanium in the region 100 gradually (and preferably monotonically) increases with proximity to the overlying layer 10b. For example, the atomic percentage may increase from about X % (where, for example, X=0 to 3, more preferably closer to or equal to 0) at or near the substrate SB to Y % (where, for example, Y=6 to 10, more preferably closer to or equal to 10) at or near the layer 10b.

Whereas in the embodiment in FIG. 1, the region 100 is formed by a homogeneous alloy of silicon-germanium, FIG. 2 instead shows an embodiment where the region is formed by an alternation of layers of silicon 110 and layers of silicon-germanium 111.

The volume percentage of germanium for each of these silicon-germanium layers 111 is chosen so that the mean final volume percentage of germanium in the region 100 is comprised between 3 and 10%. The concentration of dopants (P type) in the alternating layers 110, 110 is, for example, zero (not intentionally doped) or around 10¹⁵ or 2×10¹⁵ at/cm³ or even less. The concentration of dopants (P type) in the layer 10, located above the alternating layers 110, 111, is around 10¹⁸ to 4×10¹⁸ at/cm³.

This stack forming the region 100 is located above the N-doped buried layer 11 and under the P-doped silicon layer 10.

In this embodiment, the region 100 is also located at a distance d from the top face FS of the substrate SB1.

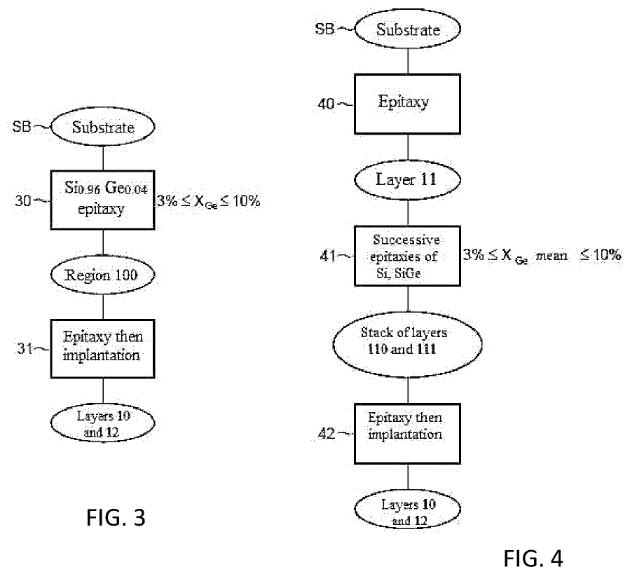

Reference is now made more particularly to FIG. 3 in order to illustrate an embodiment of a method for manufacturing the active zone 1 of the module in FIG. 1.

On the substrate SB, an epitaxy 30 is performed so as to form the region 100 consisting of 96% silicon in atomic percentage and 4% germanium in atomic percentage.

A silicon-germanium epitaxy is a step well known to persons skilled in the art.

By way of example, the SiGe epitaxy may be performed by chemical vapor deposition (acronym CVD) using a dichlorosilane+germanium+hydrogen chemistry at 900°-950° C. and at low pressure (10-60 Torr).

The epitaxy 30 is then followed by another epitaxy 31, this time solely of silicon, conventional and known per se, so as to form the top part 10b of the layer 10.

This epitaxy is preferentially P-doped (10¹⁵ to 10¹⁶ at/cm³) and the P-type doping (10¹⁸ at/cm³) is then obtained in a localized fashion by ion implantation.

By way of example, the conditions of this epitaxy are substantially the same as those used for the SiGe epitaxy, optionally with a temperature increased from 50° to 100° C.

It should be noted that these two epitaxies, often performed at the same step, may be performed in the same epitaxy operation, and therefore in the same epitaxy reactor and with the same recipe, and therefore often without cooling of the wafer between the two types of deposition.

After implantation of dopants in the upper epitaxed region, the layer 12 is obtained.

As for the layer 11, it can be obtained, for example, by an implantation of N-type dopants prior to the SiGe epitaxy.

Reference is now made more particularly to FIG. 4, which illustrates an example of implementation of a method for obtaining the active zone 1 of the module illustrated in FIG. 2.

On the support substrate SB, an epitaxy 40 of silicon is this time performed so as to form the layer 11 (N-type electrode) and then successive alternating epitaxies of silicon and silicon-germanium, referenced 41, so as to obtain the stack of layers 110 and 111.

The volume percentage of germanium for each of these epitaxies is chosen so that the mean final volume percentage of germanium is comprised between 3 and 10%.

In a variant, the layer 11 (N-type electrode) may be obtained, for example, by an implantation of N-type dopants prior to the successive epitaxies of silicon and silicon-germanium.

After the production of the stack of layers 110 and 111, an epitaxy and then an implantation 42 are once again performed so as to form the layers 10 and 12.

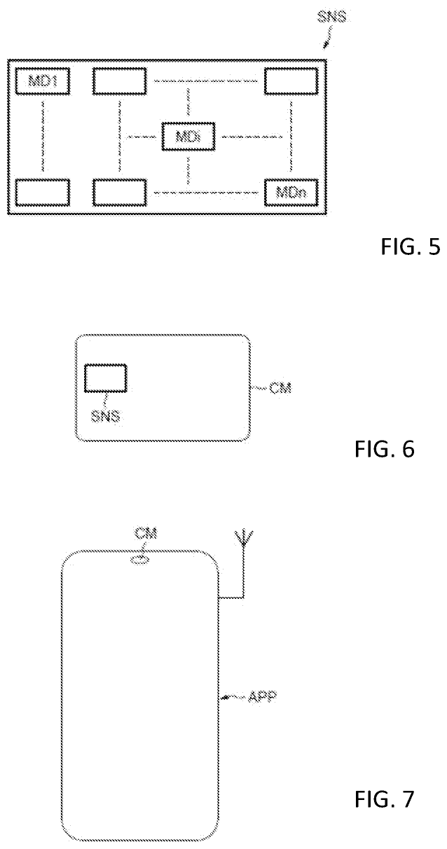

As illustrated in FIG. 5, an integrated optical sensor SNS may comprise a plurality of detection modules MD1-MDn arranged for example in rows or in a matrix.

As illustrated in FIG. 6, the sensor SNS may be incorporated in an imaging system CM, for example a camera that can itself be incorporated in an electronic apparatus APP (FIG. 7), for example of the tablet or cellular mobile telephone type.

The invention is not limited to the embodiments and implementations described above but embraces all variants.

Thus the following implementation is possible, starting from a bulk substrate:

epitaxy of silicon (boron doping at 10¹⁵ at/cm³) over a few micrometers;

localized implantation with an N-type dopant in order to form the bottom electrode of the sensor;

epitaxy of silicon-germanium or epitaxies of silicon/silicon-germanium in alternation, with potentially a “sublayer” of silicon) over a thickness of approximately 1 micrometer with an intentionally zero or very low doping (below 10¹⁵ at/cm³);

epitaxy of a layer of silicon over a thickness of approximately 0.5 micrometers with an intentionally zero or very low doping (below 10¹⁵ at/cm³), with often the same recipe as the previous epitaxy;

localized implantation of a P-type dopant in order to form the top electrode of the sensor, optionally followed by an implantation annealing;

superficial localized implantation of a P-type dopant with a high dose optionally followed by an implantation annealing, in order to form the contact zone.

It should be noted that these annealings may be mutualized and may be or are advantageously common with the other annealings used in the technology in question for manufacturing other components of the integrated circuit.

Thus, for example, the second annealing may correspond to the annealing for activation of the source/drain regions of MOS transistors.

The substrate may advantageously be formed by a wafer (P+ wafer (2×10¹⁸-2×10¹⁹ at/cm³)) covered with a P− epitaxy typically 10¹⁵-10¹⁶ at/cm³. This P+ substrate thus makes it possible to protect the sensor from metallic contaminations (getter effect) and forms a better ground plane (reduction in electronic noise).

Whereas the above description relates to the use of an N-type bottom electrode and a P-type top electrode, often advantageous for managing the ground and electrical voltages, it would also be possible to use an SPAD sensor with a P-type bottom electrode and an N-type top electrode.

1. An integrated optical sensor, comprising:
at least one photon-detection module of a single-photon avalanche photodiode type;
wherein said at least one photon-detection module comprises:
a substrate; and
a semiconducting active zone in the substrate containing germanium, wherein the semiconducting active zone comprises a region containing silicon and germanium and an atomic percentage of germanium in said semiconducting active zone is between 3% and 10%.

2. The sensor according to claim 1, wherein the region contains a silicon germanium alloy.

3. The sensor according to claim 2, wherein the region comprises a N-type doped region formed by said silicon germanium alloy and an overlying undoped region formed by said silicon germanium alloy.

4. The sensor according to claim 3, further comprising a p-type doped layer overlying the undoped region.

5. The sensor according to claim 2, wherein the region comprises a N-type doped region formed by said silicon germanium alloy and an overlying lightly P-type doped region formed by said silicon germanium alloy.

6. The sensor according to claim 5, further comprising a P-type doped layer overlying the undoped region.

7. The sensor according to claim 1, wherein the region contains an alternation of layers of silicon and layers of silicon-germanium.

8. The sensor according to claim 7, wherein the alternation of layers overlies an n-type doped layer and a P-type doped layer overlies the alternation of layers.

9. The sensor according to claim 7, wherein the alternation of layers are undoped.

10. The sensor according to claim 1, wherein the substrate comprises a top face and a top of said region is located at a distance from said top face.

11. The sensor according to claim 10, further comprising a layer of silicon located between said top face and the top of said region.

12. The sensor according to claim 1, wherein the atomic percentage of germanium in said semiconducting active zone exhibits a concentration gradient over a thickness of said semiconducting active zone.

13. The sensor according to claim 12, wherein the concentration gradient changes from an atomic percentage of germanium of about 3% at a location closer to a bottom of the semiconducting active zone to an atomic percentage of germanium of about 10% at a location closer to a top of the semiconducting active zone.

14. The sensor according to claim 1, wherein the sensor includes a plurality of photon-detection modules.

15. The sensor according to claim 1, wherein the sensor is a component of an imaging system.

16. The sensor according to claim 15, wherein the imaging system is a component of an electronic apparatus selected from a group consisting of a tablet or a cellular mobile telephone.

17. A method for producing an optical sensor including at least one photon-detection module of a single-photon avalanche photodiode type, the method comprising:
forming a semiconducting active zone of said at least one at least one photon-detection module in a substrate;
wherein the at least one at least one photon-detection module contains germanium; and
wherein forming the semiconducting active zone comprises forming a region containing silicon and germanium with an atomic percentage of germanium in said region that is between 3% and 10%.

18. The method according to claim 17, wherein forming said region comprises epitaxially producing a layer of a silicon germanium alloy.

19. The method according to claim 17, wherein forming said region comprises producing an alternation of layers of silicon and layers of silicon-germanium by successive epitaxies.

20. The method according to claim 19, wherein forming the semiconducting active zone further comprises epitaxially producing a layer of P-type conductivity silicon covering said region.

21. The method according to claim 19, further comprising forming an electrode with N-type conductivity of the sensor by localized ion implantation implemented before the formation by epitaxy of the region containing silicon and germanium.

22. The method according to claim 17, wherein forming said region comprises forming a concentration gradient for the atomic percentage of germanium in said semiconducting active zone, said gradient extending over a thickness of said semiconducting active zone.

23. The method according to claim 22, wherein the concentration gradient changes from an atomic percentage of germanium of about 3% at a location closer to a bottom of the semiconducting active zone to an atomic percentage of germanium of about 10% at a location closer to a top of the semiconducting active zone.
